(19) United States
(12) Patent Application Publication
(10) Pub. No.: US 2017/0287847 A1
(43) Pub. Date: Oct. 5, 2017

(54) INTEGRATED CIRCUIT PACKAGE HAVING INTEGRATED EMI SHIELD

(71) Applicants: Rajendra C. Dias, Phoenix, AZ (US); Robert L. Sankman, Phoenix, AZ (US); Joshua D. Heppner, Chandler, AZ (US); Mitul B. Modi, Phoenix, AZ (US); Yoshihiro Tomita, Tsukuba-Shi (JP)

(72) Inventors: Rajendra C. Dias, Phoenix, AZ (US); Robert L. Sankman, Phoenix, AZ (US); Joshua D. Heppner, Chandler, AZ (US); Mitul B. Modi, Phoenix, AZ (US); Yoshihiro Tomita, Tsukuba-Shi (JP)

(21) Appl. No.: 15/088,857

(22) Filed: Apr. 1, 2016

(51) Int. Cl. H01L 23/552; H01L 21/56; H01L 23/538; H01L 21/48; H01L 23/498; H01L 23/31

(52) U.S. Cl. CPC H01L 23/552; H01L 23/49827; H01L 23/49838; H01L 23/3128; H01L 23/5389; H01L 23/49822; H01L 23/3135; H01L 23/3142; H01L 21/4853; H01L 21/56; H01L 21/486

(57) ABSTRACT

Apparatus and methods are provided for an integrated circuit package that includes an integrated EMI shield. In an example, an integrated circuit package can include an integrated circuit mounted to a substrate via connections on the bottom surface of the integrated circuit, a conductive fence surrounding side surfaces of the integrated circuit, a conductive film coupled to the conductive fence, the film located above a top surface of the integrated circuit and coextensive with a footprint defined by the conductive fence.

### TECHNICAL FIELD

The disclosure herein relates generally to integrated circuit packages and more particularly to electromagnetic interference (EMI) shields for such structures.

### BACKGROUND

Current EMI shielding for molded system in package (SiP) use a physical vapor deposition (PVD) sputtering process to coat the mold surface with a conductive material. The sputtering process has many disadvantages including high cost of the sputtering equipment, long through put time to increase conductive material thickness, complex process for uniform material coverage on package sidewalls, mold surface pre-clean to improve adhesion etc. In the case of EMI shielding between components, laser trenches are made between components and filled with a conductive material. The expensive laser ablation tool and long process for laser trenching can negatively impact cost and throughput time in high volume manufacturing.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIGS. 1A and 1B illustrate generally an example of at least a portion of an integrated circuit package that includes an integrated EMI shield or EMI fence.

FIG. 2A-2E illustrates generally a graphical flow associated with a method of forming a through-mold EMI shield for an integrated circuit die.

FIGS. 3A-3C illustrate generally a device including a substrate integrated EMI shield according to an example of the present subject matter.

FIG. 3D illustrates generally a cross-section of stacked vias having a different stacking pattern than the device of FIG. 3C.

FIG. 4 illustrates generally a device 400 including an EMI shield according to an example of the present subject matter.

FIG. 5 illustrates generally a flowchart of a method for providing an EMI shielded integrated circuit.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present inventors have recognized apparatus and techniques for providing EMI shielding of integrated circuits assembled within integrated packages. In certain examples, an EMI shield can be integrated within over mold material surrounding an integrated circuit with an integrated circuit package. In some examples, an EMI shield can be integrated with a substrate and can be positioned about a cavity of the substrate that houses an integrated circuit. In some examples, an EMI shield can be built up about an integrated circuit housed in a cavity of a substrate. Each of the above examples, can use standard package fabrication methods including, but not limited to, formation of through mold interconnections, package via formation, cavity package construction, etc. Such methods can typically offer lower cost and short processing times to provide an EMI shield. In each case, the high cost of the sputtering equipment, long through put time to increase conductive material thickness and complex process for uniform material coverage on package sidewalls can be avoided. In addition, the package form factor and thickness are not increased by the above EMI shielding solutions.

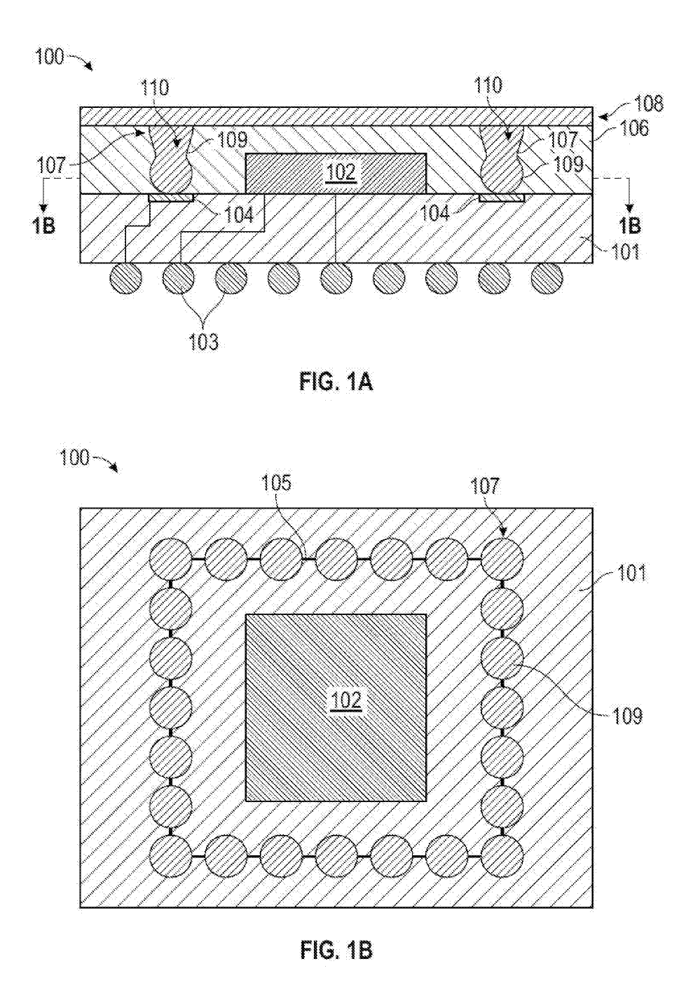

FIGS. 1A and 1B illustrate generally an example of at least a portion of an integrated circuit package 100 that includes an integrated EMI shield. In certain examples, the integrated circuit package 100 can include a substrate 101, an integrated circuit die 102, external solder balls 103, ground pads 104, substrate traces 105, over-mold mold material 106, sidewall EMI shields 107, and a top-side EMI shield 108. In certain examples, the integrated circuit die 102 is mounted to terminations (not shown) of the substrate 101, for example via terminals on the underside or bottom of the integrated circuit die 102. The substrate 101 can include wire traces 105 and routing structures to connect the appropriate termination of the integrated circuit die 102 to the external solder balls 103 of the substrate 101. The top surface of the substrate can include ground pads 104 that surround the integrated circuit die 102 when the integrated circuit die 102 is mounted to the substrate 101. In some examples, the ground pads 104 are electrically coupled to each other using conductive traces 105 of the substrate 101. In some examples, the ground pads 104 are electrically coupled to each other using conductive traces of the mold material. In some examples, additional conductive material can optionally be coupled to the grounding pads prior to adding the mold material 106. Such additional conductive material can include, but is not limited to, solder balls 109. After the mold material 106 is over molded around the integrated circuit die 102 and around the surrounding substrate surfaces, including the ground pads 104, holes 110 can be bored through the mold material 106 to each ground pad 104 or corresponding solder ball 109. The holes 110 can be filled with conductive material to form the sidewall EMI shields 107 or sidewall EMI fence. In certain examples, the over-mold mold material 106 can encapsulate the integrated circuit 102 about the side surfaces and the top surface and can house the conductive fence or sidewall EMI shields 107. In certain examples, a foil, film or sheet 108 of conductive material can be attached to the upper surface of the mold material 106 and the sheet 108 of conductive material can be electrically coupled to the conductive material that forms the sidewall EMI shields 107. The sheet 108 can be coextensive with the footprint defined by the sidewall EMI shields 107. In some examples, the substrate 101 can have multiple layers and one of the layers of the substrate 101 can optionally include a mesh of conductive material. The mesh can serve as a lower-side EMI shield of the integrated circuit die 102 and can be electrically coupled to the sidewall shields. Electrical connections between the integrated circuit die 102 and the solder balls 103 on the lower side of the substrate 101 can be routed through openings of the mesh. FIG. 1A illustrates generally a cross-section of an integrated circuit package 100 that includes sidewall EMI shields 107 and a top-side EMI shield 108. FIG. 1B illustrates generally a top-view cross-section of the integrated circuit package 100 of FIG. 1A that includes conductive traces 105 between the ground pads (not shown) and corresponding solder balls 109 of the sidewall EMI shields 107 that surround the integrated circuit die 102.

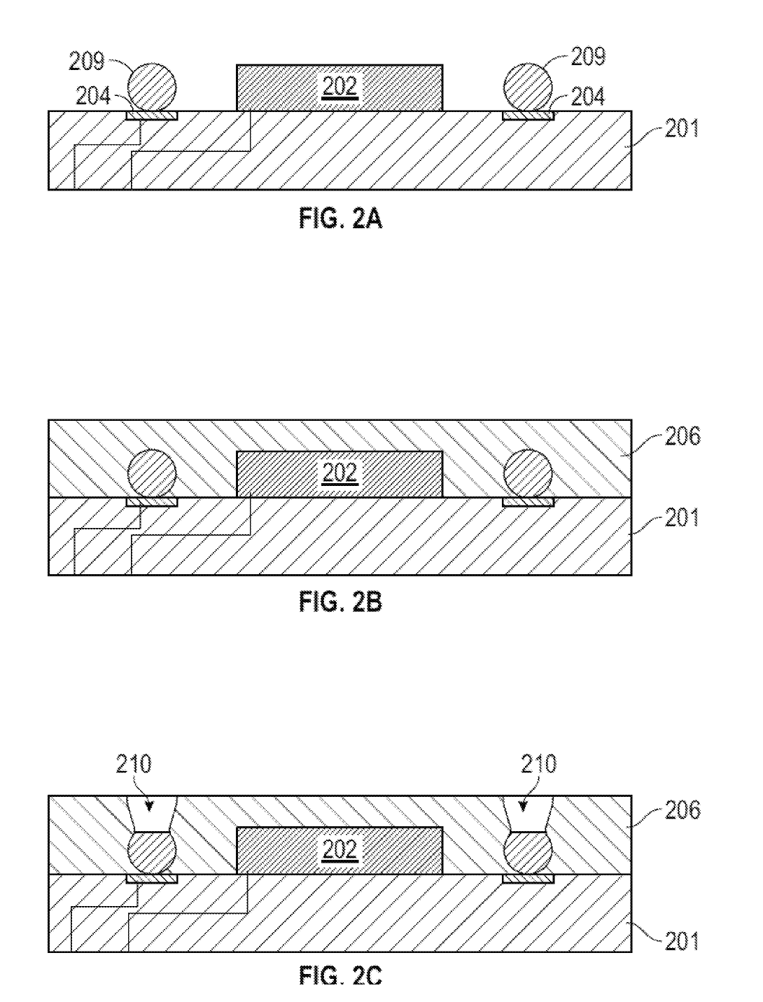

FIG. 2A-2E illustrates generally a graphical flow associated with a method of forming a through-mold EMI shield for an integrated circuit die 202. FIG. 2A shows the integrated circuit die 202 attached to a substrate 201 and solder balls 209 or conductive paste attached to ground pads 104 on the surface of the substrate 201. The substrate 201 can include routing structures (not shown) to appropriately connect terminations of the integrated circuit die 202 with terminations on the lower side of the substrate 201. At FIG. 213, a molding compound 206 is added to encapsulate the integrated circuit die and the upper surface of the substrate surrounding the integrated circuit die 202. At FIG. 2C, holes 210 can be created or bored through the molding compound 206 to extend to and expose the solder balls 209 or conductive paste associated with the grounding pads 204. In some examples, the holes 209 can be bored to expose a portion of each grounding pad 204. In certain examples, the holes 209 can be bored using laser ablation or other boring methods. At FIG. 2D, the holes 209 can be filled with electrically conductive material 211. At FIG. 2E, an electrically conductive sheet 208 can be applied to the top surface of the molding compound 206 and can be connected to the conductive material 211 filling the holes 210 to complete the through-mold EMI shield of the integrated circuit die 202. In certain examples, external solder balls 203 or external terminations can be added to the substrate 201.

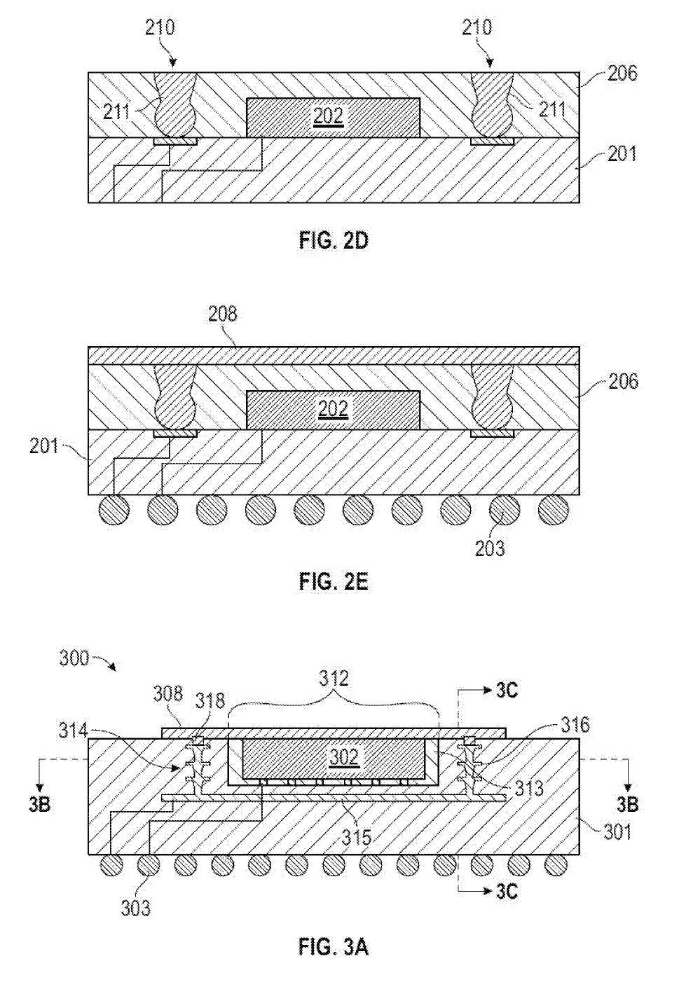

FIGS. 3A-3D illustrate generally a device 300 including a substrate integrated EMI shield according to an example of the present subject matter. In certain examples, the device 300 includes a substrate 301, and an integrated circuit die 302. The integrated circuit die 302 can be mounted to the substrate 301 within a cavity 312 of the substrate 301. Upon mounting the integrated circuit die 302 in the cavity, underfill material. 313 can be used to secure fill voids between the interior surfaces of the substrate cavity 312 and the integrated circuit die 302. In addition to assisting secure and immobilize the die, the underfill material 313 can isolated and protect the electrical connections between the integrated circuit die 302 and the substrate 301.

In certain examples, the substrate 301 can include routing structures (not shown) to electrically connect terminations of the integrated circuit die 302 with external terminations 303 of the substrate 301 such as, but not limited to, solder balls located on an underside of the substrate. In certain examples, the substrate 301 can include a series of closely stacked vias 314 that surround the cavity 312. In certain examples, the substrate 301 can include multiple layers and the stacked vias can include alternating layers of conductive pads 316 and conductive vias, The vias and conductive pads 316 can be coupled directly together and integrated with each of the multiple layers of the substrate 301 to form the stacked vias 314. The stacked vias 314 can be coupled to an optional grounding plane or a ground terminal of the substrate 301. In certain examples, the stacked vias 314 can include a conductive material or paste 318 located at a top surface of the substrate. A conductive sheet 308 or foil can span the top of the cavity 312 and can be electrically coupled to the stacked vias 314 for example, via the conductive paste 318. The conductive sheet 308 and stacked vias 314 can form an EMI shield about the integrated circuit die 302. In certain examples, the substrate 301 can optionally include a lower conductive mesh 315 to provide EMI shielding underneath the integrated circuit die 302. Openings in the underlying conductive mesh 315 can be used to route electrical connections between the integrated circuit die 302 and external connections 303 on the underside of the substrate 301. FIG, 313 illustrates a top-down cross-section of the device 300 and shows that traces 305 can be used to electrically connect the stacked vias 314. In some examples, the traces 305 can be located on one or more of the substrate layers.

FIG. 3C illustrates a cross-section of the stacked vias 314. In certain examples, the stacked vias 314 can be electrically coupled together using a conductive trace or a conductive mesh 315 of the substrate 301. FIG. 3D illustrates generally a cross-section of stacked vias 317 having a different stacking pattern than the device 300 of FIG. 3C. The stacking pattern of the stacked vias 317 of FIG. 3C uses lateral' offset vias as opposed to the vertically aligned vias of the device of FIG. 3C.

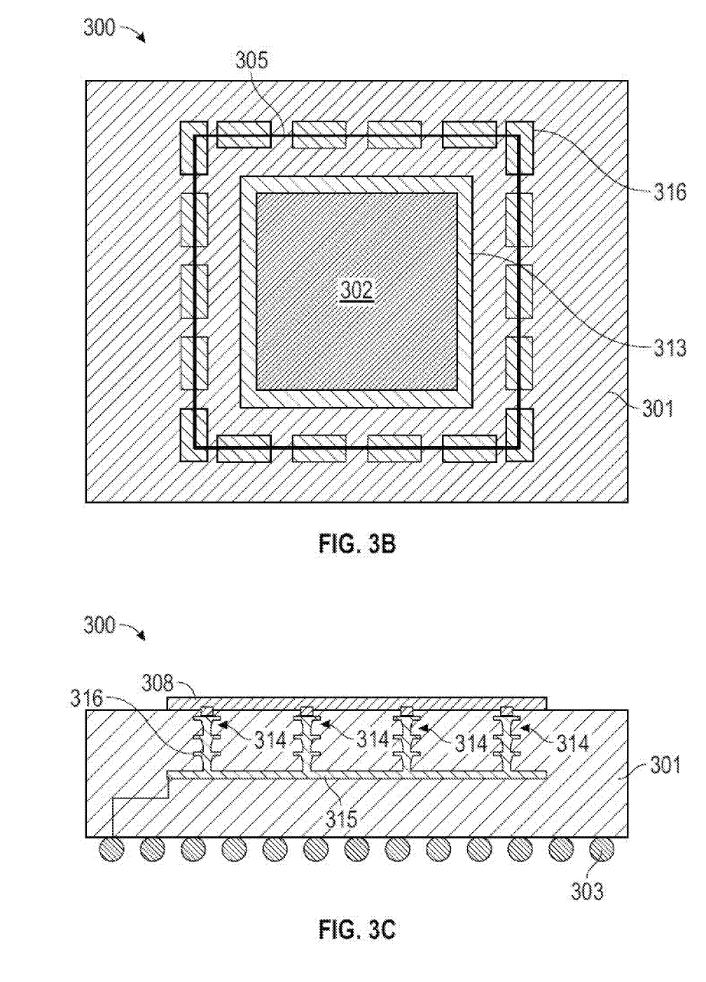

FIG. 4 illustrates generally a device 400 including an EMI shield according to an example of the present subject matter. In certain examples, the device 400 includes a substrate 401, and an integrated circuit die 402. The integrated circuit die 402 can be mounted to the substrate within a cavity 412 of the substrate 401. Upon mounting the integrated circuit die 402 in the cavity 412, underfill material 413 can be used to fill voids between the lower interior surface of the substrate cavity 412 and the integrated circuit die 402. In addition to assisting secure and immobilize the integrated circuit die 402, the underfill material 413 can isolated and protect the electrical connections 420 between the integrated circuit die 402 and the substrate 401. The remaining voids about the sidewalls of the cavity 412 and the sidewalk of the integrated circuit die 402 can be filled with conductive material 419 such as a conductive paste to create an EMI shield about the sidewalls. In certain examples, the substrate 401 can include grounding terminals 421 on one or more layers of the substrate 401. In certain examples, the grounding terminals 421 can be exposed at the sidewalls of the cavity 412 and can electrically couple the conductive material 419 of the EMI shield with ground or other reference voltage level. In certain examples, a sheet of conductive material 408 can be placed over the cavity 412 and over the integrated circuit die 402. The sheet 408 can be electrically coupled to the conductive material 419 of the EMI shield about the sidewalls or to a grounding terminal 421 exposed at the upper surface of the substrate 401.

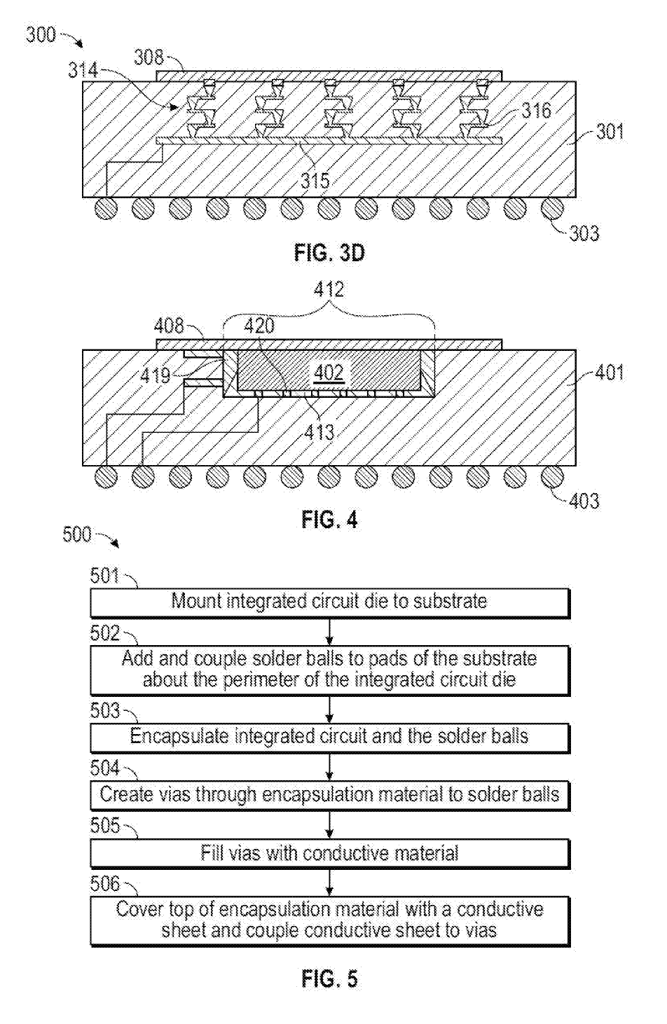

FIG. 5 illustrates generally a flowchart of a method for providing a EMI shielded integrated circuit. At 501, an integrated circuit can be mounted to and electrically couple with a substrate. In certain examples, the integrated circuit die can be mounted on a top surface of the substrate. At 502, a plurality of solder balls can be electrically coupled to a plurality of pads located about a perimeter of the integrated circuit die. At 503, the integrated circuit die and the solder balls can be encapsulated within a non-conductive material. At 504, a plurality of vias can be created in the non-conductive compound via a surface of the non-conductive compound opposite the substrate. Each via can extend to a corresponding solder ball. At 505, the vias can be filled or lined with conductive material. At 506, a conductive sheet can cover the upper surface of the nonconductive material and can be electrically coupled with the conductive material filling or lining the vias. In some examples, the pads of the substrate can be electrically coupled together such as by traces of the substrate. In some examples, one or more of the pads can be coupled to an external termination of the substrate such as an external solder ball of the substrate.

### ADDITIONAL EXAMPLES AND NOTES

In Example 1, an integrated circuit package can include an integrated circuit mounted to a substrate via connections on a first major surface (e.g., bottom) of the integrated circuit, a conductive fence surrounding side surfaces of the integrated circuit, and a conductive film coupled to the conductive fence, the film located above a second major surface (e.g., top) of the integrated circuit and coextensive with a footprint defined by the conductive fence, the second major surface of the integrated circuit opposite the first major surface of the integrated circuit.

In Example 2, the integrated circuit package of Example 1 optionally includes an over-mold configured to encapsulate the integrated circuit about the side surfaces and the second major surface and to house the conductive fence.

In Example 3, the conductive fence of any one or more of Examples 1-2 optionally includes a plurality of solder balls coupled to a plurality of ground pads on a first major surface of the substrate.

in Example 4, the integrated circuit of any one or more of Examples 1-3 optionally is positioned within a cavity of the substrate.

in Example 5, the substrate of any one or more of Examples 1-4 optionally includes the conductive fence surrounding the side surfaces of the integrated circuit and a second conductive fence underlying the integrated circuit.

In Example 6, the second conductive fence of any one or more of Examples 1-5 optionally is configured to allow electrically isolated vertical connections between the integrated circuit and external connections exposed on a second major surface of the substrate, the second major surface of the substrate opposite the first major surface of the substrate.

In Example 7, the conductive fence of any one or more of Examples 1-6 optionally includes a plurality of conductive traces and a plurality of conductive vias alternately stacked within the substrate.

In Example 8, the plurality of vias of any one or more of Examples 1-7 optionally includes a first via and a second via, wherein the first via and the second via are directly coupled by a conductive trace of the plurality of conductive traces, wherein the first via and the second are positioned in different vertical layers of the substrate, and wherein the first via is laterally offset from the second via.

in Example 9, the plurality of vias of any one or more of Examples 1-3optionally includes a first via and a second via, wherein the first via and the second via are directly coupled by a conductive trace of the plurality of conductive traces, wherein the first via and the second are positioned in different vertical layers of the substrate, and wherein the first via is vertically aligned with the second via.

In Example 10, the conductive fence of any one or more of Examples 1-9 optionally includes conductive paste configured to fill at least a portion of the cavity about the integrated circuit not filled by the integrated circuit.

In Example 11, the integrated circuit package of any one or more of Examples 1-10 optionally includes underfill configured to isolate the connections on the first major surface of the integrated circuit from the conductive paste.

in Example 12, the substrate of any one or more of Examples 1-11 optionally includes a plurality of traces configured to electrically couple with the conductive paste.

In Example 13, a first conductive trace of the plurality of conductive traces of any one or more of Examples 1-12 optionally is configured to couple the conductive film to the conductive fence.

In Example 14, a first conductive trace of the plurality of conductive traces of any one or more of Examples 1-13 optionally is configured to couple the conductive fence to terminal on the second major surface of the substrate.

in Example 15, a method for providing EMI shielding for in integrated circuit package can include electrically coupling and mounting an integrated circuit to terminations on a top surface of a substrate, electrically coupling a plurality of solder balls to a plurality of pads of the substrate, the plurality of pads located about a perimeter of the integrated circuit, encapsulating the integrated circuit and the solder balls with a non-conductive compound, creating a plurality of vias in the non-conductive compound through a surface opposite the substrate, each via of the plurality of vi as extending to a solder ball of the plurality of solder balls, filling each via with a conductive material, covering the surface with a conductive sheet, and coupling the conductive sheet with the conductive material.

in Example 16, the creating a plurality of vias of any one or more of Examples 1-15 optionally includes laser ablating the non-conductive compound.

In Example 17, the method of any one or more of Examples 1-9 optionally includes electrically coupling the plurality of solder balls together to each other.

In Example 18, the method of any one or more of Examples 1-9 optionally includes electrically coupling the plurality of solder balls to a termination on a bottom side of the substrate.

in Example 19, a method for providing EMI shielding for in integrated circuit package can include creating a first conductive fence about a cavity of the substrate, electrically coupling and mounting an integrated circuit to terminations of the substrate within the cavity of the substrate, covering the cavity with a conductive sheet, and coupling the conductive sheet with the conductive fence.

In Example 20, the creating the conductive fence of any one or more of Examples 1-19 optionally includes fabricating an opening in a first layer of the substrate, the opening configured to form a portion of a sidewall of the cavity, fabricating a plurality of traces of the first layer, the plurality of traces positioned about the opening, and fabricating a plurality of conductive vias, each via coupled to a corresponding trace of the plurality of traces.

In Example 21, the creating the conductive fence of any one or more of Examples 1-20 optionally includes fabricating a second conductive fence within a second layer of the substrate, the second conductive fence configured to underlie the cavity.

In Example 22, the method of any one or more of Examples 1-9 optionally includes coupling the second conductive fence with the first conductive fence.

Each of these non-limiting examples can stand on its own, or can be combined with one or more of the other examples in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein,” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

1. An integrated circuit package comprising:
an integrated circuit mounted to a substrate via connections on a first major surface of the integrated circuit;
a conductive fence surrounding side surfaces of the integrated circuit; and
a conductive film coupled to the conductive fence, the film located above a second major surface of the integrated circuit and coextensive with a footprint defined by the conductive fence, the second major surface of the integrated circuit opposite the first major surface of the integrated circuit,
wherein the integrated circuit is positioned within a cavity of the substrate;
wherein the substrate includes:
the conductive fence surrounding the side surfaces of the integrated circuit; and
a conductive mesh underlying the integrated circuit; and
wherein the conductive mesh is configured to allow electrically isolated vertical connections between the integrated circuit and external connections exposed on a second major surface of the substrate, the second major surface of the substrate opposite the first major surface of the substrate.

2-6. (canceled)

7. The integrated circuit package of claim 1, wherein the first conductive fence includes a plurality of conductive traces and a plurality of conductive vias alternately stacked within the substrate.

8. The integrated circuit package of claim 7, wherein the plurality of vias includes a first via and a second via;
wherein the first via and the second via are directly coupled by a conductive trace of the plurality of conductive traces;
wherein the first via and the second are positioned in different vertical layers of the substrate;
and wherein the first via is laterally offset from the second via.

9. The integrated circuit package of claim 7, wherein the plurality of vias includes a first via and a second via;
wherein the first via and the second via are directly coupled by a conductive trace of the plurality of conductive traces;
wherein the first via and the second are positioned in different vertical layers of the substrate; and
wherein the first via is vertically aligned with the second via.

10. The integrated circuit package of claim 1, wherein the conductive fence includes conductive paste configured to fill at least a portion of the cavity about the integrated circuit not filled by the integrated circuit.

11. The integrated circuit package of claim 10, including underfill configured to isolate the connections on the first major surface of the integrated circuit from the conductive paste.

12. The integrated circuit package of claim 10, wherein the substrate includes a plurality of traces configured to electrically couple with the conductive paste.

13. The integrated circuit package of claim 12, wherein a first conductive trace of the plurality of conductive traces is configured to couple the conductive film to the conductive fence.

14. The integrated circuit package of claim 12, wherein a first conductive trace of the plurality of conductive traces is configured to couple the conductive fence to terminal on the second major surface of the substrate.

15-18. (canceled)

19. A method for providing EMI shielding for in integrated circuit package, the method comprising;
creating a first conductive fence about a cavity of the substrate;
electrically coupling and mounting an integrated circuit to terminations of the substrate within the cavity of the substrate;
covering the cavity with a conductive sheet; and
coupling the conductive sheet with the conductive fence;
wherein creating the conductive fence includes:
fabricating an opening in a first layer of the substrate, the opening configured to form a portion of a sidewall of the cavity;
fabricating a plurality of traces of the first layer, the plurality of traces positioned about the opening;
fabricating a plurality of conductive vias, each via coupled to a corresponding trace of the plurality of traces; and
fabricating a conductive mesh within a second layer of the substrate, the conductive mesh configured to underlie the cavity and to allow electrically isolated vertical connections between the integrated circuit and external connections exposed on a major surface of the substrate underlying the cavity.

20-21. (canceled)

22. The method of claim 19, including coupling the second conductive mesh fence with the first conductive fence.
